(19) United States
(12) Patent Application Publication
(10) Pub. No.: US 2012/0222298 A1
(43) Pub. Date: Sep. 6, 2012

(54) METHOD OF CIRCUIT LAYOUT BY PHOTOSENSITIVE ENVIRONMENT-FRIENDLY INK

(75) Inventors: Cheng Yang Hsieh, Taichung City (TW); Cheng Lin Liang, Taichung City (TW)

(73) Assignee: TAIWAN NANOTECHNOLOGY CORPORATION, Taichung City (TW)

(21) Appl. No.: 13/104,438

(22) Filed: May 10, 2011

(30) Foreign Application Priority Data
Mar. 4, 2011 (TW) 100107392

(51) Int. Cl. H05K 3/10

(52) U.S. Cl. 29/846

(57) ABSTRACT

A method of circuit layout by photosensitive environment-friendly ink, which is used in a printed circuit board having a copper foil layer. The method comprises: providing photosensitive environment-friendly ink; disposing a circuit layout pattern, and injecting the photosensitive environment-friendly ink on the copper foil layer according to the circuit layout pattern to form the printed circuit board having the circuit layout pattern thereon; exposing the printed circuit board under light to have the photosensitive environment-friendly ink reacted with ultraviolet light in the light; and copper cleaning and alkaline cleaning the copper foil layer to expose the circuit layout pattern corresponding to the photosensitive environment-friendly ink on the printed circuit board. The invention can be used to achieve reducing steps in the conventional printed circuit board manufacturing process, reduced usage of chemical materials, simplified transfer of manufacturing process, optimization of wirings in the circuit layout, and low cost manufacture.

### FIELD OF THE INVENTION

The present invention relates to a method of circuit layout by photosensitive environment-friendly ink, and particularly to a method of providing circuit layout on a printed circuit board using photosensitive environment-friendly ink.

### BACKGROUND

In conventional technology, a printed circuit board (PCB) is a circuit board with its circuitry pattern being produced by a printing process. With the enhanced requirement of the wiring resolution of the layout on the printed circuit board, there is a need to improve the conventional manufacturing process of the printed circuit board. Nowadays most printed circuit boards are manufactured by pressing film or coating of etching resist, passing through the exposure and developing processes, performing etching to remove the exposed copper foils and to form the wirings, and then washing and removing the etching resist to finish the manufacturing process. However, with the reduced size and precision of electronic products, the PCB manufacturing process also requires reduced size and precision. Thus, ultraviolet curing ink is used as the etching resist of improved PCB manufacturing process, which further reduces the two required baking procedures in the conventional silkscreen printing or other inkjet printing processes and increases the PCB manufacturing efficiency and yield. The most critical technology in this improved manufacturing process includes the ink used and the method of circuit layout.

Therefore, in view of the aforementioned conventional problems, there is a need for a method of circuit layout by photosensitive environment-friendly ink to form the circuit layout on the copper foil layer of a printed circuit board.

### SUMMARY OF THE INVENTION

An objective of the present invention is to provide a method of circuit layout by photosensitive environment-friendly ink, which is capable of providing circuit layout on the copper foil layer of a printed circuit board by injecting photosensitive environment-friendly ink directly on the printed circuit board.

Another objective of the present invention is to provide a method of circuit layout by photosensitive environment-friendly ink, which uses photosensitive environment-friendly photo-curing ink to directly provide the circuit layout on the copper foil layer of a printed circuit board by.

To achieve the foregoing objectives of the invention, the invention provides a method of circuit layout by photosensitive environment-friendly ink, which is used in a printed circuit board having a copper foil layer. The method comprises: providing photosensitive environment-friendly ink; disposing a circuit layout pattern, and injecting the photosensitive environment-friendly ink on the copper foil layer according to the circuit layout pattern to form the printed circuit board having the circuit layout pattern thereon; exposing the printed circuit board under light to have the photosensitive environment-friendly ink reacted with ultraviolet light in the light; and copper cleaning and alkaline cleaning the copper foil layer to expose the circuit layout pattern corresponding to the photosensitive environment-friendly ink on the printed circuit board. The photosensitive environment-friendly ink can comprise at least one of photopolymerized prepolymer, photosensitive monomer, photopolymerization initiator, mixed solvent, environment-friendly color paste, and additive; and the photosensitive environment-friendly ink is nanometer sized, with its surface tension of the photosensitive environment-friendly ink between 22 and 24 N/m.

Comparing to the conventional technology, the present invention provides a method of circuit layout by photosensitive environment-friendly ink, which is capable of reducing the complicated steps in the pre-manufacturing process of the printed circuit board including pre-made mask sheets, coating copper foils, exposure and developing. In other words, the present invention utilizes inkjet controlling technology to inject the perform photosensitive environment-friendly ink through the nozzle to generate layout on specific areas on the printed circuit board having a copper foil layer to form the circuit layout pattern, thus producing the printed circuit board with the circuit layout pattern. Referring to the surface of the printed circuit board, the manufacturing process is similar to the printing process of a document. Furthermore, the ink of the invention has the characteristics of being environment-friendly, safe for storage, suited to hard base materials such as printed circuit boards, wear proof, chemical proof, heat resistance, quick drying, low ink bleeding, and high resolution.

### BRIEF DESCRIPTION OF THE DRAWINGS

FIG. 1 is a flow chart of an embodiment of the method of circuit layout by photosensitive environment-friendly ink of the present invention.

### DETAILED DESCRIPTION OF THE INVENTION

The techniques employed by the present invention to achieve the foregoing objectives, characteristics and effects thereof are described hereinafter by way of examples with reference to the accompanying drawings.

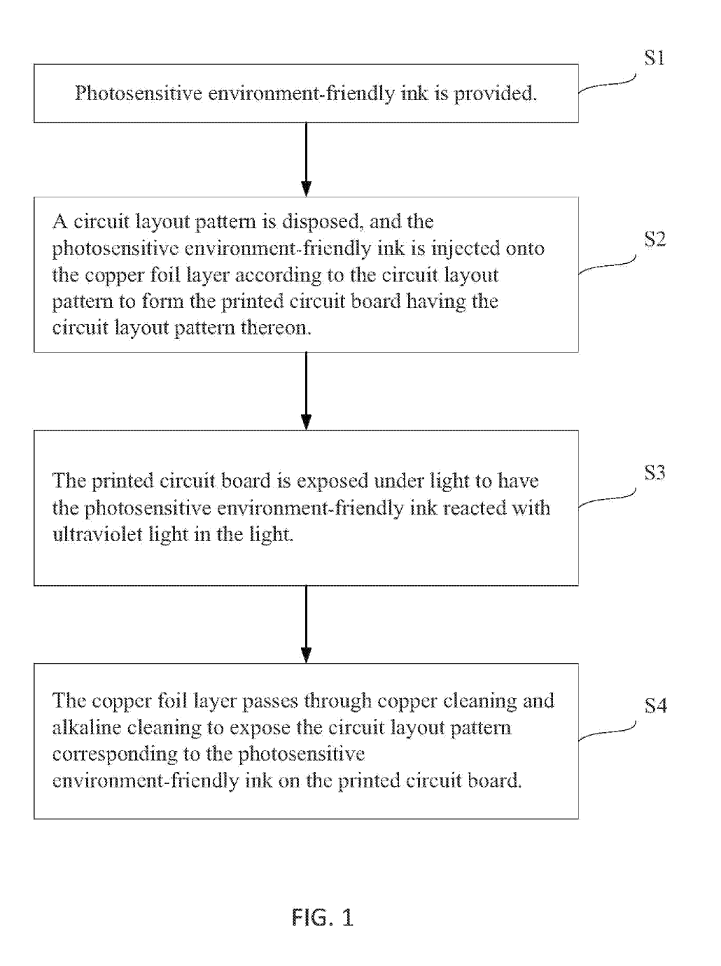

Referring to FIG. 1, which shows a flow chart of an embodiment of the method of circuit layout by photosensitive environment-friendly ink of the present invention. In FIG. 1, the method of circuit layout by photosensitive environment-friendly ink is used in a printed circuit board having a copper foil layer. The steps comprises: in step S1, photosensitive environment-friendly ink is provided. In step S2, a circuit layout pattern is disposed, and the photosensitive environment-friendly ink is injected onto the copper foil layer according to the circuit layout pattern to form the printed circuit board having the circuit layout pattern thereon. In step S3, the printed circuit board is exposed under light to have the photosensitive environment-friendly ink reacted with ultraviolet light in the light. Lastly, in step S4, the copper foil layer passes through copper cleaning and alkaline cleaning to expose the circuit layout pattern corresponding to the photosensitive environment-friendly ink on the printed circuit board.

The light is at least one of visible light and invisible light. Wavelength of the invisible light can be in an ultraviolet region between 250 nm and 400 nm, and it should be noted that wavelength of the invisible light can be one of 395 nm, 405 nm or 450 nm. Wavelength of the visible light can be in a visible region between 400 nm and 800 nm.

In addition, the photosensitive environment-friendly ink can comprise at least one of photopolymerized prepolymer, photosensitive monomer, photopolymerization initiator, mixed solvent, environment-friendly color paste, and additive. The photoinitiator in the photosensitive environment-friendly ink is a compound that can be optically excited, that is, the ink can be exposed under the light and become free radical, and the energy is transferred to photosensitive particles or photocrosslinkers such that photo-curing reaction occurs to the photosensitive environment-friendly ink.

Furthermore, the photopolymerized prepolymer, also referred to as oligomer, is a low molecular polymer having unsaturated groups, and is the major component of the photosensitive environment-friendly ink. As to its chemical formulation, the photopolymerized prepolymer is a low molecular resin having the C=C unsaturated double bond, and the average molecular weight is between hundreds to thousands. The oligmer can be epoxy acrylate, polyurethane acrylate, polyester acrylate, and alkali soluble acrylic acid resin.

The photosensitive monomer is a low molecular compound having unsaturated groups (e.g. double bond) which would react with the oligomer under exposure of the light to crosslink, and the average molecular weight is between hundreds to thousands. Furthermore, the viscosity of the photosensitive environment-friendly ink can be adjusted by adding reactive diluents into the prepolymer, thus controlling the curing crosslinking density of the ink and improving the physical characteristics of the cured material, such as flexibility and hardness. The reactive diluents can be monofunctional group diluents or multifunctional group diluents, and the multifunctional group diluents are better than the monofunctional group diluents in the dilution effect and photo-curing speed. The reactive diluents are critical to the curing process of the ink and characteristics of the cured film, and it is essential to choose proper reactive diluents. Generally, physical characteristics such as viscosity, functionality, volatility, smell, toxicity and solubility should be considered for the photosensitive monomer. Typical reactive diluents include tripropylene glycol diacrylate (TPGDA), triethylene glycol diacrylate (TEGDA), and trimethylolpropane triacrylate (TMPTA).

The photoinitiator is an essential component for photo-curing, and can be dissolved to become free radical under light exposure to activate polymerization and crosslinking reaction. In other words, the photoinitiator would absorb photons to be excited to become free radical, and the energy is transferred to high molecular polymers to perform chain reactions such that the resin becomes a mesh structure to form an ink cured film. It is difficult for the light to break the double bond of the photopolymerized prepolymer, so without the photopolymerization initiator, it would be difficult for photosensitive materials to rapidly cure. Thus, a small amount of the photopolymerization initiator would be added to the ink such that, when the ink with the photopolymerization initiator is under light exposure, the photoinitiator would absorb photons to be excited to become free radical to activate reactions for unsaturated double bond to polymerize, and the polymer molecules would crosslink to generate the mesh structure to form a cured ink after the free radical loses activity and the bonds stop increasing. The photoinitiator can be photopolymerization initiator, and can be at least one of cracking initiator, photoinitiator, and cationic initiator.

The mixed solvent is used for diluting the ink and being a carrier of the ink. The type and quantity of ingredients of the mixed solvent greatly affect the stability of the ink. The mixed solvent should be obtained by choosing from organic solvents such as low boiling point alcohol, high boiling point alcohol, ether, heterocyclic amine, and cyclic ester, and selecting the best combination for the ink such that stability, viscosity, surface tension and conductivity of the ink composition fit the commercial requirements of the ink composition. In an embodiment, the mixed solvent is selected from a group consisting of ethyl acetate, butyl acetate, and isopropyl acetate.

The environment-friendly color paste can be polymerized toners with nanoparticles, and the size of the toners is smaller than 300 nm. In another embodiment, the size of the toners can be between 50 nm and 100 nm.

The additive can further comprise at least one of emulsifier, surfactant, and ultraviolent absorbent. The emulsifier has significant surface activity to form surface films around fluid drops, create electric barriers on the surface of fluid drops, and increase viscosity of the surface. The emulsifier also provides stability for the ink composition in relation to acids, alkalis and salts, and is not irritable.

The emulsifier can further comprises surfactant, which refers to substances reducing the surface tension of the ink composition or reducing surface tension between two fluids. For example, the surface tension of the photosensitive environment-friendly ink can be between 22 and 24 N/m. The surfactant can be organic amphiphilic molecules with hydrophilic and hydrophobic groups, which is dissolvable to organic solution and water solution. In addition to reduce the surface tension of the ink composition, the surfactant also provides functions such as lubricating, permeating, dispersing and emulsifying. The surfactant can be categorized as ionic surfactant, nonionic surfactant, and amphoteric surfactant. The ionic surfactant can be further categorized as cationic surfactant and anionic surfactant.

The ultraviolent absorbent (also referred to as light stabilizer) can be plural recipe type, and particularly plural recipes using benzyl benzoate, phenyl ketone, or benzotrizole instead of acrylonitrile, triasine and hindered amine groups such that the ultraviolent absorbent is easier to achieve ideal ultraviolent absorbing than single recipe ultraviolent absorbent. Furthermore, the ultraviolent absorbent is provided so that the ink composition would not easily be decomposed or allochroic.

Comparing to the conventional technology, the present invention provides a method of circuit layout by photosensitive environment-friendly ink, which is capable of reducing the complicated steps in the pre-manufacturing process of the printed circuit board including pre-made mask sheets, coating copper foils, exposure and developing. In other words, the present invention utilizes inkjet controlling technology to inject the perform photosensitive environment-friendly ink through the nozzle to generate layout on specific areas on the printed circuit board having a copper foil layer to form the circuit layout pattern, thus producing the printed circuit board with the circuit layout pattern. Referring to the surface of the printed circuit board, the manufacturing process is similar to the printing process of a document. Furthermore, the ink of the invention has the characteristics of being environment-friendly, safe for storage, suited to hard base materials such as printed circuit boards, wear proof, chemical proof, heat resistance, quick drying, low ink bleeding, and high resolution.

The preferred embodiments of the present invention have been disclosed in the examples. However, the examples should not be construed as a limitation on the actual applicable scope of the invention, and as such, all modifications and alterations without departing from the spirits of the invention and appended claims shall remain within the protected scope and claims of the invention.

What is claimed is:

1. A method of circuit layout by photosensitive environment-friendly ink used in a printed circuit board having a copper foil layer, the method comprising:
providing photosensitive environment-friendly ink;
disposing a circuit layout pattern, and injecting the photosensitive environment-friendly ink on the copper foil layer according to the circuit layout pattern to form the printed circuit board having the circuit layout pattern thereon;
exposing the printed circuit board under light to have the photosensitive environment-friendly ink reacted with ultraviolet light in the light; and
copper cleaning and alkaline cleaning the copper foil layer to expose the circuit layout pattern corresponding to the photosensitive environment-friendly ink on the printed circuit board.

2. The method of circuit layout by photosensitive environment-friendly ink as claimed in claim 1, wherein the photosensitive environment-friendly ink comprises at least one of photopolymerized prepolymer, photosensitive monomer, photopolymerization initiator, mixed solvent, environment-friendly color paste, and additive.

3. The method of circuit layout by photosensitive environment-friendly ink as claimed in claim 2, wherein the mixed solvent is selected from a group consisting of ethyl acetate, butyl acetate, and isopropyl acetate.

4. The method of circuit layout by photosensitive environment-friendly ink as claimed in claim 2, wherein the additive further comprises at least one of emulsifier, surfactant, and ultraviolent absorbent.

5. The method of circuit layout by photosensitive environment-friendly ink as claimed in claim 2, wherein surface tension of the photosensitive environment-friendly ink is between 22 and 24 N/m.

6. The method of circuit layout by photosensitive environment-friendly ink as claimed in claim 2, wherein the environment-friendly color paste comprises toners having nanoparticles, and size of the toners is smaller than 300 nanometers.

7. The method of circuit layout by photosensitive environment-friendly ink as claimed in claim 6, wherein size of the toners is between 50 nanometers and 100 nanometers.

8. The method of circuit layout by photosensitive environment-friendly ink as claimed in claim 2, wherein the photopolymerization initiator is at least one of cracking initiator, photoinitiator, and cationic initiator.

9. The method of circuit layout by photosensitive environment-friendly ink as claimed in claim 1, wherein the light is at least one of visible light and invisible light.

10. The method of circuit layout by photosensitive environment-friendly ink as claimed in claim 9, wherein wavelength of the invisible light is in an ultraviolet region between 250 nm and 400 nm.

11. The method of circuit layout by photosensitive environment-friendly ink as claimed in claim 9, wherein wavelength of the invisible light is one of 395 nm, 405 nm or 450 nm.

12. The method of circuit layout by photosensitive environment-friendly ink as claimed in claim 9, wherein wavelength of the visible light is in a visible region between 400 nm and 800 nm.
